(19) United States
(12) Patent Application Publication
(10) Pub. No.: US 2026/0271547 A1
(43) Pub. Date: Sep. 10, 2026

(54) DISPLAY DEVICE INCLUDING STACKED ANODE CONNECTION STRUCTURE, AND ELECTRONIC DEVICE USING THE SAME

(71) Applicant: SAMSUNG DISPLAY CO., LTD., YONGIN-SI (KR)

(72) Inventors: Thanh Tien NGUYEN, Yongin-si (KR); Han Bit KIM, Yongin-si (KR); Myoung Geun CHA, Yongin-si (KR); Sang Gun CHOI, Yongin-si (KR)

(21) Appl. No.: 19/358,912

(22) Filed: Oct. 15, 2025

(30) Foreign Application Priority Data
Mar. 4, 2025 (KR) 10-2025-0027371
Apr. 16, 2025 (KR) 10-2025-0049292

(51) Int. Cl. H10K 59/123; H10K 59/121; H10K 59/131

(52) U.S. Cl. CPC H10K 59/123; H10K 59/1213; H10K 59/131

(57) ABSTRACT

A display device includes a substrate having an emission area and a non-emission area. A thin-film transistor layer is disposed on the substrate and includes a driving transistor. A display element layer is disposed on the thin-film transistor layer and includes an anode electrode electrically connected to the driving transistor. The thin-film transistor layer includes a first anode connection electrode disposed between the driving transistor and the anode electrode, a second anode connection electrode disposed on the first anode connection electrode, and a third anode connection electrode disposed on the second anode connection electrode, electrically connected to the anode electrode, and including a semiconductor material. The first anode connection electrode, the second anode connection electrode, the third anode connection electrode, and the anode electrode overlap one another in a direction perpendicular to a surface of the substrate and are disposed in different layers.

This application claims priority under 35 U.S.C. §119 to Korean Patent Application No. 10-2025-0027371, filed in the Korean Intellectual Property Office on March 4, 2025 and Korean Patent Application No. 10-2025-0049292, filed in the Korean Intellectual Property Office on April 16, 2025, the contents of which are incorporated by reference herein in their entirety.

### TECHNICAL FIELD

The present disclosure relates to a display device and, more specifically, to a display device including a stacked anode connection structure and an electronic device using the same.

### DISCUSSION OF THE RELATED ART

As the information-oriented society evolves, display devices are finding their way into more devices. Display devices may be flat panel display devices such as a liquid-crystal display device, a field emission display device, and a light-emitting display device. Light-emitting display devices may include an organic light-emitting display device including an organic light-emitting element, an inorganic light-emitting display device including an inorganic light-emitting element such as an inorganic semiconductor, and a micro-light-emitting display device including an ultra-small light-emitting element.

In high-resolution display devices, a plurality of conductive layers included in a thin-film transistor layer of a display device may be stacked and arranged within a narrow area, and the size of transistors may be reduced.

### SUMMARY

A display device includes a substrate having an emission area and a non-emission area. A thin-film transistor layer is disposed on the substrate and includes a driving transistor. A display element layer is disposed on the thin-film transistor layer and includes an anode electrode electrically connected to the driving transistor. The thin-film transistor layer includes a first anode connection electrode disposed between the driving transistor and the anode electrode. A second anode connection electrode is disposed on the first anode connection electrode. A third anode connection electrode is disposed on the second anode connection electrode, electrically connected to the anode electrode, and including a semiconductor material. The first anode connection electrode, the second anode connection electrode, the third anode connection electrode, and the anode electrode overlap one another in a direction perpendicular to a surface of the substrate and are disposed in different layers.

The driving transistor may include a channel region, a source region and a drain region, and a length of the channel region of the driving transistor may be equal to or less than 3.0 micrometers.

The display device may further include a switching transistor disposed between the driving transistor and the first anode connection electrode. The switching transistor may include a channel region, a source region, and a drain region. The switching transistor may be electrically connected to the drain region of the driving transistor. A length of the channel region of the switching transistor may be equal to or less than 3.0 micrometers.

The switching transistor may further include a low-concentration region having a lower doping concentration than the drain region of the switching transistor. The low-concentration region of the switching transistor may be electrically connected to the drain region of the switching transistor on an opposite side to a side where the channel region of the switching transistor is disposed.

The low-concentration region may overlap the third anode connection electrode in the direction perpendicular to the surface of the substrate.

The thin-film transistor layer may include a first gate conductive layer disposed on the channel region of the driving transistor. A second gate conductive layer may be disposed on the first gate conductive layer. An oxide semiconductor layer may be disposed on the second gate conductive layer. A third gate conductive layer may be disposed on the oxide semiconductor layer. A first source/drain conductive layer may be disposed on the third gate conductive layer. The first source/drain conductive layer may include the first anode connection electrode.

The thin-film transistor layer may further include a second source/drain conductive layer disposed on the first source/drain conductive layer. The second source/drain conductive layer may include the second anode connection electrode. The second source/drain conductive layer may further include a vertical voltage line and a data line.

The thin-film transistor layer may further include a third source/drain conductive layer disposed on the second source/drain conductive layer. The third source/drain conductive layer may include the third anode connection electrode.

The third anode connection electrode may be disposed between the data line and the anode electrode.

The second anode connection electrode may be electrically connected to the first anode connection electrode through a first anode contact hole. The third anode connection electrode may be electrically connected to the second anode connection electrode through a second anode contact hole. The anode electrode may be electrically connected to the third anode connection electrode through a third anode contact hole.

The second anode contact hole may be spaced apart from the third anode contact hole, in a plan view.

The first anode connection electrode, the second anode connection electrode, the third anode connection electrode, and the anode electrode may overlap one another in the direction perpendicular to the surface of the substrate, in a plan view.

An electrical resistance of the third anode connection electrode may range from 100 kΩ to 1,000 kΩ.

The third anode connection electrode may include at least one of oxide semiconductor, amorphous silicon, and low-temperature polycrystalline silicon.

An electronic device includes at least one display device including a substrate having an emission area and a non-emission area. At least one of a display module, a processor, a memory, and a power module are electrically connected to the display device. The at least one display device includes a thin-film transistor layer disposed on the substrate and including a driving transistor. A display element layer is disposed on the thin-film transistor layer and includes an anode electrode electrically connected to the driving transistor. The thin-film transistor layer includes a first anode connection electrode disposed between the driving transistor and the anode electrode. A second anode connection electrode is disposed on the first anode connection electrode. A third anode connection electrode is disposed on the second anode connection electrode, electrically connected to the anode electrode, and including a semiconductor material. The first anode connection electrode, the second anode connection electrode, the third anode connection electrode, and the anode electrode overlap one another in a direction perpendicular to a surface of the substrate and are disposed in different layers.

The driving transistor may include a channel region, a source region, and a drain region. A length of the channel region of the driving transistor may be equal to or less than 3.0 micrometers.

The electronic device may further include a switching transistor disposed between the driving transistor and the first anode connection electrode. The switching transistor may include a channel region, a source region, and a drain region. The switching transistor may be electrically connected to the drain region of the driving transistor. A length of the channel region of the switching transistor may be equal to or less than 3.0 micrometers.

The thin-film transistor layer may include a first gate conductive layer disposed on the channel region of the driving transistor. A second gate conductive layer may be disposed on the first gate conductive layer. An oxide semiconductor layer may be disposed on the second gate conductive layer. A third gate conductive layer may be disposed on the oxide semiconductor layer. A first source/drain conductive layer may be disposed on the third gate conductive layer. The first source/drain conductive layer may include the first anode connection electrode.

The thin-film transistor layer may further include a second source/drain conductive layer disposed on the first source/drain conductive layer. A third source/drain conductive layer may be disposed on the second source/drain conductive layer. The second source/drain conductive layer may include a vertical voltage line, a data line, and the second anode connection electrode. The third source/drain conductive layer may include the third anode connection electrode.

An electrical resistance of the third anode connection electrode may range from 100 kΩ to 1,000 kΩ, and the third anode connection electrode may include at least one of an oxide semiconductor, an amorphous silicon, or a low-temperature polycrystalline silicon.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view of a display device according to an embodiment of the present disclosure.

FIG. 2 is a block diagram illustrating a display device according to the embodiment of the present disclosure.

FIG. 3 is an equivalent circuit diagram of a sub-pixel according to an embodiment of the present disclosure.

FIG. 4 is a layout diagram of sub-pixels in a display area according to an embodiment of the present disclosure.

FIG. 5 is a layout diagram illustrating an example of the equivalent circuit diagram of FIG. 3.

FIG. 6 is a cross-sectional view taken along line X1 – X1' of FIG. 5.

FIG. 7 is a layout diagram illustrating an example of the first semiconductor layer and the first gate conductive layer in FIG. 5.

FIG. 8 is an enlarged cross-sectional view of area T of FIG. 6.

FIG. 9 is a layout diagram illustrating an example of the second gate conductive layer, the second semiconductor layer, the third gate conductive layer, and the first source/drain conductive layer in FIG. 5.

FIG. 10 is a layout diagram illustrating an example of the second source/drain conductive layer in FIG. 5.

FIG. 11 is a layout diagram illustrating an example of the third source/drain conductive layer in FIG. 5.

FIG. 12 is a plan view illustrating the layout of the first to third anode connection electrodes and the anode electrodes in FIG. 6.

FIG. 13 is a plan view illustrating an example of the layout of the first to third anode connection electrodes and the anode electrodes in FIG. 6.

FIG. 14 is a block diagram of an electronic device according to an embodiment of the present disclosure.

FIG. 15 is a perspective view illustrating electronic devices according to a variety of embodiments of the present disclosure.

### DETAILED DESCRIPTION OF THE EMBODIMENTS

Aspects and features of the present disclosure and methods of accomplishing the same may be understood more readily by reference to the following detailed description of embodiments and the accompanying drawings. The present disclosure may, however, be embodied in many different forms and should not necessarily be construed as being limited to the embodiments set forth herein. Rather, these embodiments are provided so that this disclosure will be thorough and complete and will fully convey the concept of the present disclosure to those skilled in the art.

It will be understood that when an element or layer is referred to as being "on” another element or layer, the element or layer can be directly on another element or layer or intervening elements or layers. Like reference numerals may refer to like elements throughout the specification and the drawings. While each drawing may represent one or more particular embodiments of the present disclosure, drawn to scale, such that the relative shapes, sizes, ratios, angles, numbers, lengths, and thicknesses can be inferred therefrom, it is to be understood that the present invention is not necessarily limited to the relative dimensions. Changes to these values may be made within the spirit and scope of the present disclosure, for example, to allow for manufacturing limitations and the like.

It will be understood that, although the terms first, second, third, etc., may be used herein to describe various elements, these elements should not necessarily be limited by these terms. These terms are used to distinguish one element from another element. Thus, a first element discussed below could be termed a second element without departing from the teachings of the present disclosure.

Features of various embodiments of the present disclosure may be partially or entirely coupled to or combined with each other, and may be inter-operated and driven in technically various ways. The embodiments may be implemented independently from each other, or may be implemented together in a co-dependent relationship.

Hereinafter, embodiments of the present disclosure will be described in detail with reference to the accompanying drawings.

Embodiments of the present disclosure relate to a high-resolution light-emitting display device designed to improve luminance control while maintaining a suitable driving voltage range, particularly in ultra-high-definition applications. The display device may include a layered architecture built on a substrate that includes an emission area and a non-emission area. A thin-film transistor (TFT) layer is used that integrates a driving transistor and an anode electrode for a light-emitting element, such as an OLED. Three vertically stacked anode connection electrodes may be used, each of which is disposed in a different conductive layer. These vertically stacked anodes may bridge the driving transistor and the anode electrode. The third of these electrodes is formed from a semiconductor material with specified resistive properties, serving as a resistance element to stabilize current flow between the driving transistor and the light-emitting element.

This layered anode interconnect structure enables the display device to precisely control luminance even as the dimensions of the transistors shrink to support higher pixel densities. For example, the third anode connection electrode functions as a resistive element with a resistance in the range of 100 kΩ to 1,000 kΩ, and may be composed of materials such as oxide semiconductors, amorphous silicon, or low-temperature polycrystalline silicon. This resistance moderates the driving current and prevents excessive variation in the voltage across the light-emitting element, which can otherwise occur due to reduced transistor channel lengths in high-resolution displays. By embedding this resistance structurally within the device, embodiments of the present disclosure may address the degradation of luminance control that typically accompanies transistor miniaturization.

Embodiments of the present disclosure may further support various configurations of transistors and conductive layers, all precisely layered and electrically connected through a sequence of vias and contact holes. These elements may be fabricated using advanced materials and structures, including multiple gate layers, insulating layers, and stacked via connections to route voltages and signals. Together, these structural innovations provide stable and precise emission performance, enabling use in a wide range of electronic products, from smartphones and tablets to wearable displays and televisions. The overall architecture may achieve improved grayscale performance, enhanced driving stability, and adaptability for flexible or rigid display platforms, thereby offering a scalable solution for next-generation display technologies.

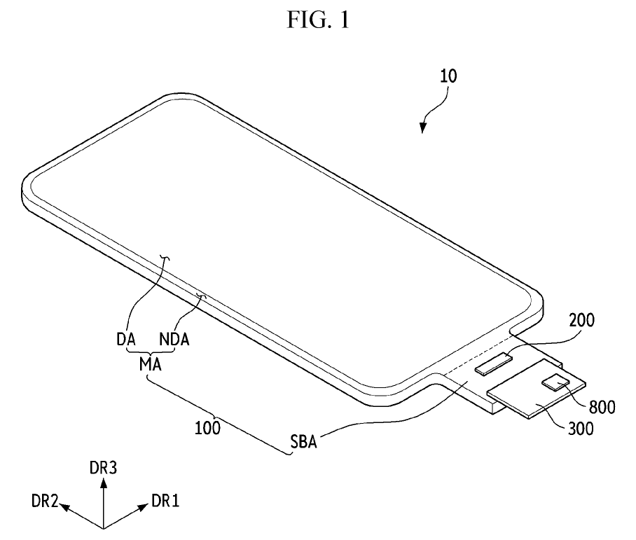

FIG. 1 is a perspective view showing a display device according to an embodiment of the present disclosure.

Referring to FIG. 1, a display device 10 may be employed by portable electronic devices such as a mobile phone, a smart phone, a tablet computer, a mobile communications terminal, an electronic notebook, an electronic book, a portable multimedia player (PMP), a navigation device, and an ultra mobile PC (UMPC). For example, the display device 10 may be used as a display unit of a television, a laptop/notebook computer, a computer monitor, an electronic billboard, or the Internet of Things (IOT) device. For an example, the display device 10 may be applied to wearable devices such as a smart watch, a watch phone, a glasses-type display, and a head-mounted display (HMD) device.

The display device 10 may have a shape similar to a quadrilateral shape, in a plan view. For example, the display device 10 may have a shape similar to a rectangle having a pair of shorter sides extending in a first direction DR1 and a pair of longer sides extending in a second direction DR2. The corners where the shorter sides extending in the first direction DR1 meet the longer sides extending in the second direction DR2 may be rounded with a predetermined curvature or may be a right angle. The shape of the display device 10, in a plan view, is not necessarily limited to a quadrilateral shape, but may be formed in a shape similar to other polygonal shapes, a circular shape, or an elliptical shape.

The display device 10 may include a display panel 100, a source driver circuit 200, a circuit board 300 and a touch driver 800.

The display panel 100 may include a main area MA and a subsidiary area SBA. The main area MA may include the display area DA including pixels for displaying images, and the non-display area NDA disposed around the display area DA.

The display area DA may emit light from a plurality of emission areas or a plurality of openings to be described later. For example, the display panel 100 may include pixel circuits including switching elements, an element insulating layer that defines the emission areas or the openings, and self-light-emitting elements. For example, the self-light-emitting element may include, but is not necessarily limited to including, at least one of: an organic light-emitting diode including an organic emissive layer, a quantum-dot light-emitting diode (quantum LED) including a quantum-dot emissive layer, an inorganic light-emitting diode (inorganic LED) including an inorganic semiconductor, and a micro light-emitting diode (micro LED). In the following drawings, it is illustrated that the self-luminous element is an organic light-emitting diode.

The non-display area NDA may be disposed on the outer side of the display area DA. The non-display area NDA may be defined as the edge area of the main area MA of the display panel 100.

The subsidiary area SBA may be extended from one side of the main area MA. The subsidiary area SUB may include a flexible material that can be bent, folded, or rolled to at least a noticeable extent without cracking or otherwise sustaining damage thereto. For example, when the subsidiary area SBA is bent, the subsidiary area SBA may overlap the main area MA in the thickness direction (e.g., third direction DR3). The subsidiary area SBA may include pads electrically connected to the source driver circuit 200 and the circuit board 300. According to an embodiment, the subsidiary area SBA may be omitted, and the source driver circuit 200 and the pads may be disposed in the non-display area NDA.

The source driver circuit 200 may output signals and voltages for driving the display panel 100. The source driver circuit 200 may be implemented as an integrated circuit (IC) and may be attached on the display panel 100 by a chip-on-glass (COG) technique, a chip-on-plastic (COP) technique, or ultrasonic bonding. For example, the source driver circuit 200 may be disposed in the subsidiary area SBA and may overlap the main area MA in the thickness direction as the subsidiary area SBA is bent. For an example, the source driver circuit 200 may be mounted on the circuit board 300.

The circuit board 300 may be attached on the pad area of the display panel 100 using an anisotropic conductive film (ACF). The circuit board 300 may be a flexible printed circuit board (FPCB), a printed circuit board (PCB), or a flexible film such as a chip-on-film (COF).

The touch driver 800 may be mounted on the circuit board 300. The touch driver 800 may detect a touch and process it.

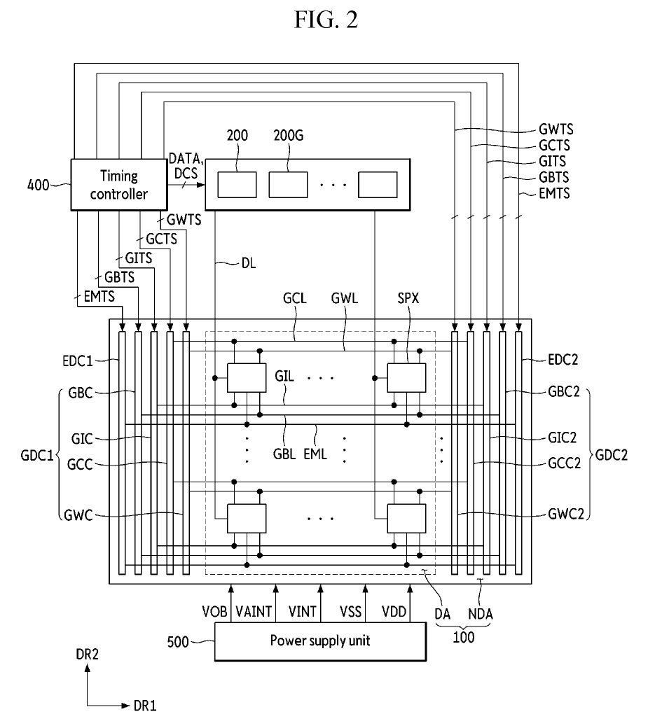

FIG. 2 is a block diagram showing a display device according to the embodiment of the present disclosure.

Referring to FIGS. 1 and 2, the display device 10, according to the embodiment, may include a plurality of sub-pixels SPX, a plurality of scan lines SL, a plurality of emission control lines EML, and a plurality of data lines DL in the display area DA. The plurality of scan lines SL may include a plurality of scan write lines GWL, a plurality of scan control lines GCL, a plurality of scan initialization lines GIL, and a plurality of bias scan lines GBL.

In addition, the display device 10 may further include a timing control circuit 400 and a power supply circuit 500. The timing control circuit 400 may generate timing control signals for controlling the timing of a scan driver circuit, an emission driver circuit, and a source control circuit. The power supply circuit 500 may generate a plurality of supply voltages for driving the display panel 100 according to an input power from an external source.

The sub-pixels SPX may be arranged in a matrix in the first direction DR1 and the second direction DR2.

Each of the plurality of sub-pixels SPX may be electrically connected to one of the plurality of scan write lines GWL, one of the plurality of scan control lines GCL, one of the plurality of scan initialization lines GIL, one of the plurality of bias scan lines GBL, one of the plurality of emission control lines EML, and one of the plurality of data lines DL.

Each of the sub-pixels SPX may receive data voltage from the data line DL according to a scan write signal from the scan write line GWL, and may allow the light-emitting element to emit light according to the data voltage.

The scan lines SL and the emission control lines EML may be extended in the first direction DR1 and may be arranged in the second direction DR2. The data lines DL may be extended in the second direction DR2 and may be arranged in the first direction DR1.

The display device 10, according to the embodiment of the present disclosure, may include a first scan driver circuit GDC1, a second scan driver circuit GDC2, a first emission driver circuit EDC1, and a second emission driver circuit EDC2 in the non-display area NDA.

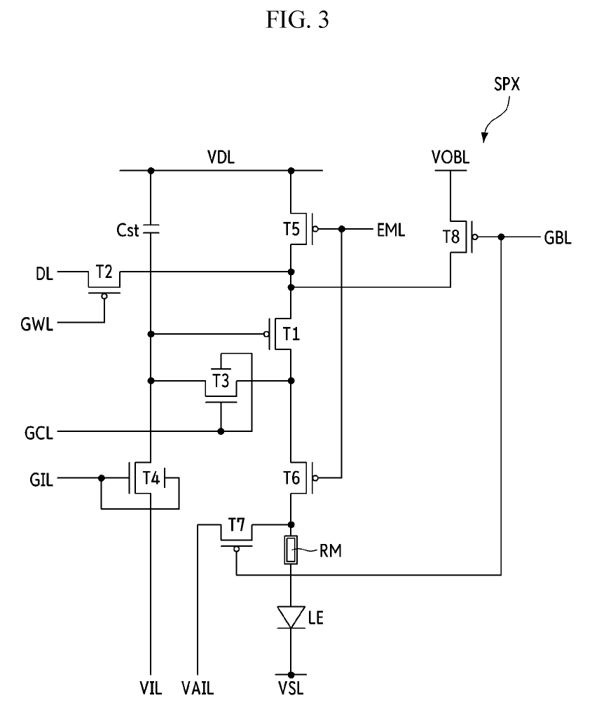

Each of the first scan driver circuit GDC1 and the second scan driver circuit GDC2 may include a scan write driver circuit GWC, a scan control driver circuit GCC, a scan initialization driver circuit GIC, and a bias scan driver circuit GBC. Although the scan write driver circuit GWC, the scan control driver circuit GCC, the scan initialization driver circuit GIC and the bias scan driver circuit GBC are arranged in this order from the display area DA to the edge of the display panel 100 in the example shown in FIG. 3, the embodiments of the present disclosure are not necessarily limited thereto.

The scan write driver circuit GWC may receive a write timing signal GWTS from the timing control circuit 400. The scan write driver circuit GWC may generate scan write signals according to the write timing signal GWTS and sequentially output them to the scan write lines GWL.

The scan control driver circuit GCC may receive a control timing signal GCTS from the timing control circuit 400. The scan control driver circuit GCC may generate scan control signals according to the control timing signal GCTS and sequentially output them to the scan control lines GCL.

The scan initialization driver circuit GIC may receive an initialization timing signal GITS from the timing control circuit 400. The scan initialization driver circuit GIC may generate scan initialization signals according to the initialization timing signal GITS and output them sequentially to the scan initialization lines GIL.

The bias scan driver circuit GBC may receive a bias timing signal GBTS from the timing control circuit 400. The bias scan driver circuit GBC may generate bias scan signals according to the bias timing signal GBTS and sequentially output them to the bias scan lines GBL.

Each of the first emission driver circuit EDC1 and the second emission driver circuit EDC2 may receive an emission timing signal ETS from the timing control circuit 400. Each of the first emission driver circuit EDC1 and the second emission driver circuit EDC2 may generate emission control signals according to the emission timing signal ETS and sequentially output them to the emission control lines EML.

A data driver circuit 200G may include a plurality of source driver circuits 200. Each of the plurality of source driver circuits 200 may receive digital video data DATA and a data timing signal DCS from the timing control circuit 400. Each of the source driver circuits 200 may convert digital video data DATA into analog data voltages according to the data timing signal DCS and output them to the data lines DL. In this instance, the sub-pixels SPX are selected by the scan write signal, and the data voltages may be provided to the selected sub-pixels SPX.

The timing control circuit 400 may receive the digital video data DATA and the timing signals TS from an external source. The timing control circuit 251 may generate the write timing signal GWTS, the control timing signal GCTS, the initialization timing signal GITS, the bias timing signal GBTS, and the emission timing signal ETS according to the timing signals TS. The timing control circuit 400 may output the write timing signal GWTS to the scan write driver circuits GWC and may output the control timing signal GCTS to the scan control driver circuits GCC. In addition, the timing control circuit 400 may output the initialization timing signal GITS to the scan initialization driver circuits GIC and may output the bias timing signal GBTS to the bias scan driver circuits GBC. The timing control circuit 400 may output the emission timing signal ETS to the first emission driver circuit EDC1 and the second emission driver circuit EDC2. In addition, the timing control circuit 400 may output the digital video data DATA and the data timing signal DCS to the source driver circuits 200.

A power supply circuit 500 may generate a plurality of panel driving voltages in response to a supply voltage from an external source. For example, the power supply circuit 500 may generate a first supply voltage VSS, a second supply voltage VDD, a third supply voltage VINT, a fourth supply voltage VAINT, and a fifth supply voltage VOB and may supply them to the display panel 100.

The first supply voltage VSS may be a low-level voltage, while the second supply voltage VDD may be a high-level voltage. The third supply voltage VINT may be a first initialization voltage, the fourth supply voltage VAINT may be a second initialization voltage, and the fifth supply voltage VOB may be a third initialization voltage. The third supply voltage VINT, the fourth supply voltage VAINT and the fifth supply voltage VOB may be higher than the first supply voltage VSS and lower than the second supply voltage VDD.

FIG. 3 is an equivalent circuit diagram of a sub-pixel according to an embodiment of the present disclosure.

Referring to FIG. 3 in conjunction with FIGS. 1 and 2, a sub-pixel SPX, according to the embodiment of the present disclosure, may be electrically connected to a scan write line GWL, a scan initialization line GIL, a scan control line GCL, a bias scan line GBL, an emission control line EML, and a data line DL.

According to the embodiment of the present disclosure, the sub-pixel SPX may include a driving transistor, switching elements, a capacitor Cst, and a light-emitting element LE. The driving transistor may include a first transistor T1, and the switching transistors may include second to eighth transistors T2, T3, T4, T5, T6, T7 and T8.

The first transistor T1 controls a source/drain current (hereinafter referred to as driving current) according to a data voltage applied to a first gate electrode. The gate electrode of the first transistor T1 may be electrically connected to a second voltage line VDL from which the second supply voltage VDD is applied. For example, the first transistor T1 may be a driving transistor. In the following descriptions, the first transistor T1 may be referred to as the driving transistor.

The light-emitting element LE may be an organic light-emitting diode. The light-emitting element LE may emit light according to the driving current described above. The luminance of the light-emitting element LE may be proportional to the driving current. A first electrode of the light-emitting element LE may be electrically connected to a first electrode of the sixth transistor T6 and a second electrode of the sixth transistor. A second electrode of the light-emitting element LE may be electrically connected to the first voltage line VSL to which the first supply voltage is applied. The first electrode of the light-emitting element LE may be an anode electrode or a pixel electrode, and the second electrode may be a cathode electrode or a cathode electrode.

The second transistor T2 is turned on by a scan write signal of a gate-on voltage applied to the scan write line GWL to connect the data line DL to the first electrode of the first transistor T1. Accordingly, a data voltage may be applied to the first electrode of the first transistor T1 while the second transistor T2 is turned on. The gate electrode of the second transistor T2 may be electrically connected to the scan write line GWL, the first electrode may be electrically connected to the data line DL, and the second electrode may be electrically connected to the first electrode of the first transistor T1.

The third transistor T3 is turned on by a scan control signal of the gate-on voltage applied to the scan control line GCL to connect the gate electrode of the first transistor T1 to the second electrode. While the third transistor T3 is turned on, the first transistor T1 may behave like a diode. The gate electrode of the third transistor T3 may be electrically connected to the scan control line GCL, the first electrode may be electrically connected to the second electrode of the first transistor T1, and the second electrode may be electrically connected to the gate electrode of the first transistor T1.

The fourth transistor T4 is turned on by a scan initialization signal of the gate-on voltage applied to the scan initialization line GIL and connects the gate electrode of the first transistor T1 to the third voltage line VIL. While the fourth transistor T4 is turned on, the gate electrode of the first transistor T1 may be initialized with the third supply voltage VINT of the third voltage line VIL. The gate electrode of the fourth transistor T4 may be electrically connected to the scan initialization line GIL, the first electrode may be electrically connected to the gate electrode of the first transistor T1, and the second electrode may be electrically connected to the third voltage line VIL.

The fifth transistor T5 is turned on by an emission control signal of the gate-on voltage applied to the emission control line EML to connect the second voltage line VDL to the first electrode of the first transistor T1. While the fifth transistor T5 is turned on, the second supply voltage VDD (see FIG. 3) of the second voltage line VDL may be applied to the first electrode of the first transistor T1. The gate electrode of the fifth transistor T5 may be electrically connected to the emission control line EML, the first electrode may be electrically connected to the second voltage line VDL, and the second electrode may be electrically connected to the first electrode of the first transistor T1.

The sixth transistor T6 is turned on by an emission control signal of the gate-on voltage applied to the emission control line EML to connect the second electrode of the first transistor T1 to the first electrode of the light-emitting element LE. While the sixth transistor T6 is turned on, the driving current of the first transistor T1 may be provided to the light-emitting element LE. The gate electrode of the sixth transistor T6 may be electrically connected to the emission control line EML, the first electrode may be electrically connected to the second electrode of the first transistor T1, and the second electrode may be electrically connected to the first electrode of the light-emitting element LE. In the following descriptions, the sixth transistor T6 may be referred to as a switching transistor electrically connected to the driving transistor.

The seventh transistor T7 is turned on by a bias scan signal of the gate-on voltage applied to the bias scan line GBL to connect the first electrode of the light-emitting element LE to a fourth voltage line VAIL. While the seventh transistor T7 is turned on, the first electrode of the light-emitting element LE may be initialized with the fourth supply voltage VAINT (see FIG. 3) of the fourth voltage line VAIL. The gate electrode of the seventh transistor T7 may be electrically connected to the bias scan line GBL, the first electrode may be electrically connected to the first electrode of the light-emitting element LE, and the second electrode may be electrically connected to the fourth voltage line VAIL.

The eighth transistor T8 is turned on by a bias scan signal of the gate-on voltage applied to the bias scan line GBL to connect the first electrode of the first transistor T1 to a fifth voltage line VOBL. While the eighth transistor T8 is turned on, the first electrode of the first transistor T1 may be initialized with the fifth supply voltage VOB (see FIG. 3) of the fifth voltage line VOBL. The gate electrode of the eighth transistor T8 may be electrically connected to the bias scan line GBL, the first electrode may be electrically connected to the first electrode of the first transistor T1, and the second electrode may be electrically connected to the fifth voltage line VOLB.

A capacitor Cst is formed between the gate electrode of the first transistor T1 and the second voltage line VDL. One electrode of the capacitor Cst may be electrically connected to the gate electrode of the first transistor T1, and the other electrode may be electrically connected to the second voltage line VDL.

The first transistor T1, the second transistor T2, the fifth transistor T5, the sixth transistor T6, the seventh transistor T7 and the eighth transistor T8 may be implemented as p-type metal oxide semiconductor field effect transistors (MOSFETs).

For example, the active layer of each of the first transistor T1, the second transistor T2, the fifth transistor T5, the sixth transistor T6, the seventh transistor T7 and the eighth transistor T8 may be made of polysilicon. In addition, the first transistor T1, the second transistor T2, the fifth transistor T5, the sixth transistor T6, the seventh transistor T7 and the eighth transistor T8 may be turned on by a signal of the gate-low voltage.

It should be understood, however, that the embodiments of the present disclosure are not necessarily limited thereto. For example, the active layer of each of the first transistor T1, the second transistor T2, the fifth transistor T5, the sixth transistor T6, the seventh transistor T7 and the eighth transistor T8 may be made of oxide semiconductor.

The third transistor T3 and the fourth transistor T4 may be implemented as n-type metal oxide semiconductor field effect transistors. In this instance, the active layer of each of the third transistor T3 and the fourth transistor T4 may be made of oxide semiconductor. In addition, the third transistor T3 and the fourth transistor T4 may be turned on by a signal of the gate-high voltage.

The display device 10, according to the embodiment of the present disclosure, may be employed in a variety of electronic devices, and thus may require high-resolution characteristics. This may mean that a plurality of conductive layers may be arranged at a high density within a narrow area, and the size of semiconductor elements may be reduced to a certain range or less.

Typically, reduction in the size of semiconductor devices in a high-resolution display may mean reduction in the length and width of the channel region of a transistor. For example, reduction in the length and width of the channel region may reduce the driving voltage range of transistors.

For example, if the driving voltage range is reduced below an appropriate level, even though the switching transistor may be turned on/off normally, the luminance control capability of the light-emitting element by the driving transistor may be deteriorated. Accordingly, in the display device 10, according to the embodiment of the present disclosure, a transistor structure is proposed that can maintain a driving voltage range at an appropriate level even in a high-resolution display device.

According to the embodiment of the present disclosure, a resistance member RM may be disposed between the first transistor T1 and the light-emitting element LE. The resistance member RM may be electrically connected between the first transistor T1 (driving transistor) and the first electrode or the second electrode of the light-emitting element LE to control the driving current, so that it is possible to prevent the driving voltage range of the driving transistor from being reduced.

The display device 10, according to the embodiment of the present disclosure, includes the resistor RM between the first transistor T1 (driving transistor) and the anode electrode of the light-emitting element LE, so that it can maintain the driving voltage range at an appropriate level. Accordingly, the display device 10, according to the embodiment of the present disclosure, can precisely adjust the luminance or grayscale of the light-emitting elements LE. More detailed descriptions will be given below.

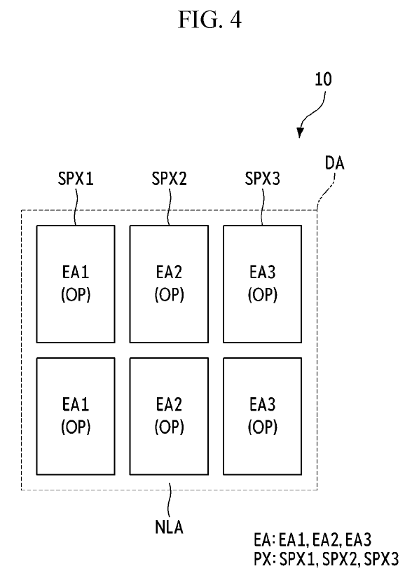

FIG. 4 is a layout diagram of sub-pixels in a display area according to an embodiment of the present disclosure.

Referring to FIG. 4, a pixel PX, according to the embodiment, may include a first sub-pixel SPX1, a second sub-pixel SPX2 and a third sub-pixel SPX3 disposed in the display area DA. The first sub-pixel SPX1, the second sub-pixel SPX2, and the third sub-pixel SPX3 may be spaced apart from one another.

The pixel PX may include emission areas EA. In the emission areas EA, light may be output. For example, the first sub-pixel SPX1 may include a first emission area EA1, the second sub-pixel SPX2 may include a second emission area EA2, and the third sub-pixel SPX3 may include a third emission area EA3.

According to the embodiment of the present disclosure, the first emission area EA1, the second emission area EA2 and the third emission area EA3 may output light of different colors. For example, the first emission area EA1 may output red light, the second emission area EA2 may output green light, and the third emission area EA3 may output blue light. It should be understood, however, that the embodiments of the present disclosure are not necessarily limited thereto. In some implementations, the first emission area EA1, the second emission area EA2 and the third emission area EA3 may output light of the same color.

The display device 10, according to the embodiment, may include a non-emission area NLA disposed in the display area DA. The non-emission area NLA may surround each of the first to third emission areas EA1, EA2 and EA3, and may assist in preventing the light output from the first to third emission areas EA1, EA2 and EA3 from being mixed.

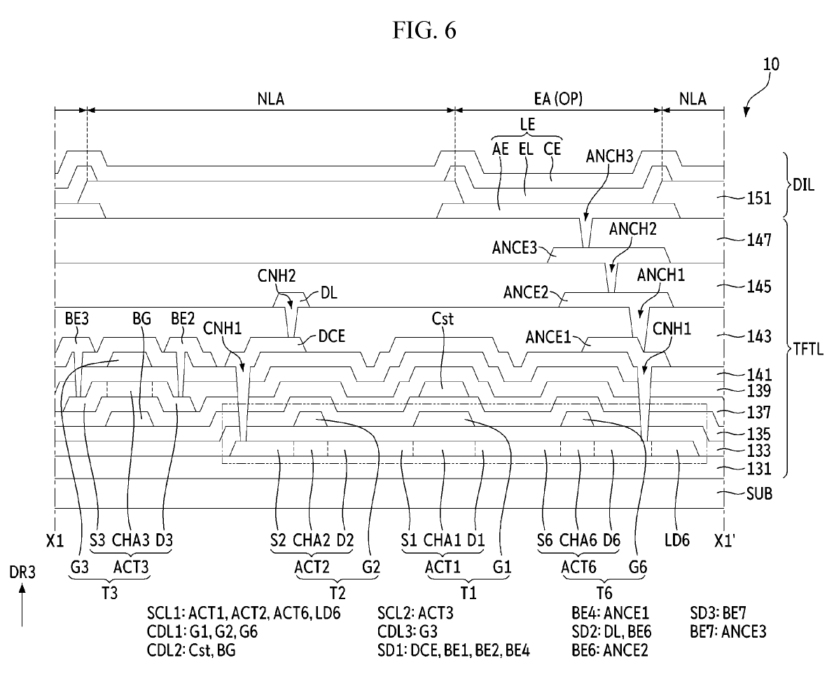

According to an embodiment of the present disclosure, the emission areas EA and the non-emission area NLA may be defined by emission areas OP. The emission openings OP may be defined by a pixel-defining layer 151 (see FIG. 6) to be described later.

Thus, display devices, according to embodiments of the present disclosure, may be designed for use in a wide range of electronic products, including mobile devices, TVs, wearables, and IoT applications. Embodiments may feature a sophisticated structure including a display panel with sub-pixels arranged in a matrix, supported by an array of scan lines, data lines, emission control lines, and various driving circuits that manage pixel activation, data input, and emission timing. Each sub-pixel may include a driving transistor, multiple switching transistors, a capacitor, and an organic light-emitting diode (OLED), with the inclusion of a resistive element between the driving transistor and the OLED anode to maintain appropriate driving voltage and enable precise luminance control even as transistor sizes shrink for high-resolution displays.

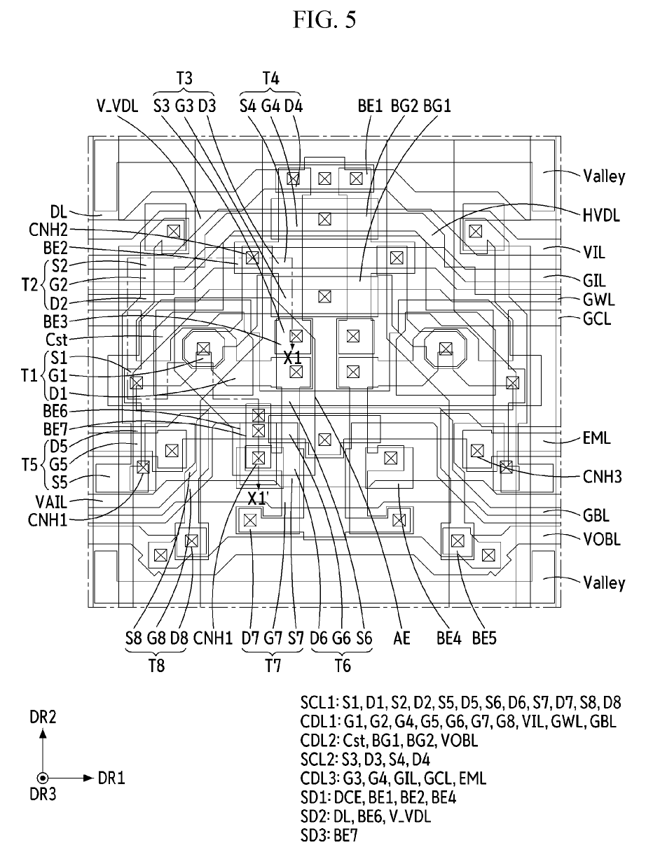

FIG. 5 is a layout diagram illustrating an example of the equivalent circuit diagram of FIG. 3. FIG. 6 is a cross-sectional view taken along line X1 – X1' of FIG. 5.

Referring to FIGS. 5 and 6 in conjunction with FIGS. 1 to 4, the display device 10 may include a substrate SUB, a thin-film transistor layer TFTL, and a display element layer DIL stacked on one another in the third direction DR3. The first to eighth transistors T1 to T8 and a plurality of conductive lines may be disposed in the thin-film transistor layer TFTL.

In a plan view, a gate electrode G1 of the first transistor T1 may be electrically connected to a third drain region D3 of the third transistor T3 and a fourth source region S4 of the fourth transistor T4 through a second bridge electrode BE2.

The first source region S1 of the first transistor T1 may be electrically connected to a second drain region D2 of the second transistor T2, and the first drain region D1 of the first transistor T1 may be electrically connected to a sixth source region S6 of the sixth transistor T6. Moreover, the first drain region D1 of the first transistor T1 may be electrically connected to a third source region S3 of the third transistor T3 through a third bridge electrode BE3.

A gate electrode G2 of the second transistor T2 may be electrically connected to the scan write line GWL extended in the first direction DR1, and a second source region S2 may be electrically connected to the data line DL. The second drain region D2 of the second transistor T2 may be electrically connected to the first source region S1 of the first transistor T1.

A gate electrode G3 of the third transistor T3 may be electrically connected to the scan control line GCL extended in the first direction DR1, the third source region S3 may be electrically connected to the second drain region D2 of the first transistor T1 through the third bridge electrode BE3, and the third drain region D3 may be electrically connected to the gate electrode G1 of the first transistor T1 through the second bridge electrode BE2.

A gate electrode G4 of the fourth transistor T4 may be electrically connected to the scan initialization line GIL extended in the first direction DR1, and the fourth source region S4 may be electrically connected to the gate electrode G1 of the first transistor T1 through the third bridge electrode BE3. In addition, the fourth source region S4 may be electrically connected to the third drain region D3. The fourth drain region D4 may be electrically connected to the third voltage line VIL extended in the first direction DR1 and may be electrically connected to the fourth drain region D4 of an adjacent sub-pixel through the first bridge electrode BE1.

One electrode of the capacitor Cst may be electrically connected to the gate electrode G1 of the first transistor T1, and the other electrode may be electrically connected to a second vertical voltage line V_VDL.

A gate electrode G5 of the fifth transistor T5 may be electrically connected to the emission control line EML through a contact hole, and the fifth source region S5 may be electrically connected to a second horizontal voltage line HVDL through a first contact hole CNH1. In addition, the fifth source region S5 may be electrically connected to the second vertical voltage line V_VDL through the first contact hole CNH1. A fifth drain region D5 may be electrically connected to the first source region S1 of the first transistor T1.

A gate electrode G6 of the sixth transistor T6 may be electrically connected to the emission control line EML, the sixth source region S6 may be electrically connected to the first drain region D1 of the first transistor T1, and the sixth drain region D6 may be electrically connected to an anode electrode AE through the first contact hole CNH1.

A gate electrode G7 of the seventh transistor T7 may be electrically connected to the bias scan line GBL extended in the first direction DR1, and a seventh source region S7 may be electrically connected to the sixth drain region D6. A seventh drain region D7 may be electrically connected to a fourth voltage line VAIL extended in the first direction DR1 through a contact hole.

A gate electrode G8 of the eighth transistor T8 may be electrically connected to the bias scan line GBL, the eighth source region S8 may be electrically connected to the first source region S1 of the first transistor T1, and the eighth drain region D8 may be electrically connected to the fifth voltage line VOLB extended in the first direction DR1.

According to the embodiment, the anode electrode AE may overlap the sixth drain region D6 of the sixth transistor T6, the seventh source region S7 of the seventh transistor T7, the gate electrode G1 of the first transistor T1, and the first drain region D1.

As shown in FIG. 6, a substrate SUB may be a rigid substrate or a flexible substrate that can be bent, folded, rolled, and so on, to at least a noticeable extent without cracking or otherwise sustaining damage thereto. The substrate SUB may be made of an electrically insulating material such as glass, quartz and a polymer resin. Examples of the polymer material may include polyethersulphone (PES), polyacrylate (PA), polyacrylate (PAR), polyetherimide (PEI), polyethylene naphthalate (PEN), polyethylene terephthalate (PET), polyphenylene sulfide (PPS), polyallylate, polyimide (PI), polycarbonate (PC), cellulose triacetate (CAT), cellulose acetate propionate (CAP) or a combination thereof. Alternatively, the substrate SUB may include a metallic material.

The thin-film transistor layer TFTL may be disposed on the substrate SUB. The thin-film transistor layer TFTL may include a plurality of insulating layers, a plurality of via layers, a plurality of semiconductor layers, and a plurality of conductive layers.

For example, the plurality of insulating layers included in the thin-film transistor layer TFTL may include a buffer layer 131, a first gate insulator 133, a second gate insulator 135, a first interlayer dielectric layer 137, a third gate insulator 139, and a second interlayer dielectric layer 141.

The plurality of insulating layers included in the thin-film transistor layer TFTL may include an inorganic insulating material. For example, the inorganic insulating material may be made of silicon nitride (SiNx), silicon oxide nitride (SiON), silicon oxide (SiOx), titanium oxide (TiOx), or aluminum oxide (AlOx).

The plurality of via layers included in the thin-film transistor layer TFTL may include a first via layer 143, a second via layer 145, and a third via layer 147.

The plurality of via layers included in the thin-film transistor layer TFTL may include an organic material. For example, the organic material may include an acrylic resin, a silicone resin, a silicone acrylic resin, an epoxy resin, polyimide, polyamide, benzocyclobutene, a phenol resin, etc.

In addition, the thin-film transistor layer TFTL according to the embodiment of the present disclosure may include a first semiconductor layer SCL1a first gate conductive layer CDL1, a second gate conductive layer CDL2, a second semiconductor layer SCL2, a third gate conductive layer CDL3, a first source/drain conductive layer SD1, a second source/drain conductive layer SD2, and a third source/drain conductive layer SD3 that are sequentially stacked on one another. More detailed descriptions will be given below.

According to the embodiment of the present disclosure, the buffer layer 131 may be disposed on the substrate SUB. The buffer layer 131 can protect the conductive layers included in the thin-film transistor layer TFTL from moisture permeating through the substrate SUB vulnerable to permeation of moisture.

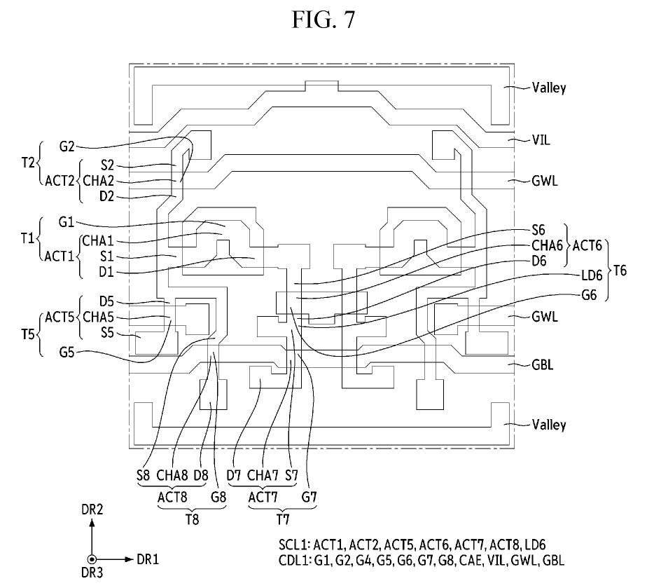

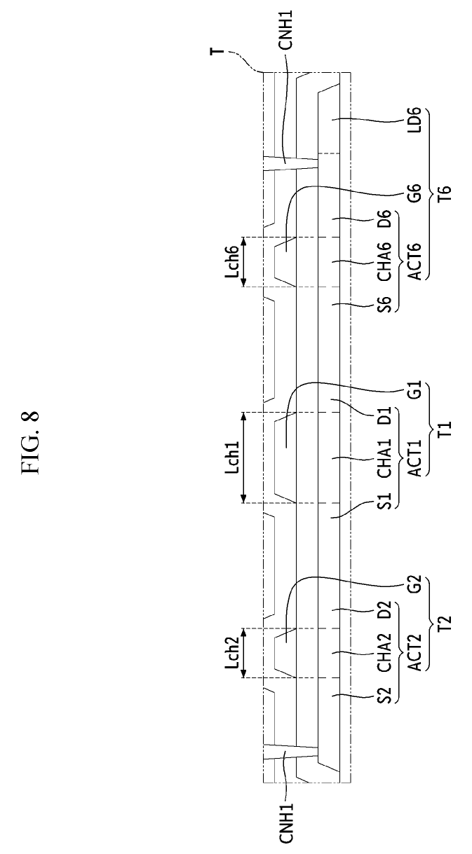

FIG. 7 is a layout diagram illustrating an example of the first semiconductor layer and the first gate conductive layer in FIG. 5. FIG. 8 is an enlarged cross-sectional view of area T of FIG. 6.

Referring to FIGS. 5 to 8, the first semiconductor layer SCL1 may be disposed on the buffer layer 131. The first semiconductor layer SCL1 may include polysilicon such as polycrystalline silicon, single-crystal silicon, low-temperature polycrystalline silicon, and amorphous silicon.

According to the embodiment, the first semiconductor layer SCL1 may include a first active layer ACT1 of the first transistor T1, a second active layer ACT2 of the second transistor T2, a fifth active layer ACT5 of the fifth transistor T5, a sixth active layer ACT6 of the sixth transistor T6, a low-concentration doping region LD6 of the sixth transistor T6, a seventh active layer ACT7 of the seventh transistor T7, and an eighth active layer ACT8 of the eighth transistor T8.

The first active layer ACT1 may include a first channel region CHA1, a first source region S1 and a first drain region D1, and the first channel region CHA1 may overlap a gate electrode G1 included in the first gate conductive layer CDL1 in the third direction DR3 that is the thickness direction of the substrate SUB. As used herein, the third direction DR3 may be defined as the thickness direction of the substrate SUB or the thickness direction of the display device 10.

As described above, as the display device 10, according to the embodiment, is applied to a high-resolution electronic device, the length of the channel region may be equal to or less than a certain value. For example, the length Lch1 of the first channel region CHA1, according to the embodiment, may be less than or equal to 3.0 micrometers.

The first source region S1 may be disposed on one side of the first channel region CHA1, and the first drain region D1 may be disposed on the opposite side of the first channel region CHA1. The first source region S1 and the first drain region D1 might not overlap the gate electrode G1 in the third direction DR3. The first source region S1 and the first drain region D1 may have a desired conductivity by doping a semiconductor material with ions.

The second active layer ACT2 may include a second channel region CHA2, a second source region S2 and a second drain region D2. The second channel region CHA1 may overlap the gate electrode G2 in the third direction DR3 that is the thickness direction of the substrate SUB.

According to the embodiment, the length Lch2 of the second channel region CHA2 may be equal to or less than 3.0 micrometers. To the extent that an element is not described in detail with respect to this figure, it may be understood that the element is at least similar to a corresponding element that has been described elsewhere within the present disclosure.

The second source region S2 may be disposed on one side of the second channel region CHA2, and the second drain region D2 may be disposed on the other side of the second channel region CHA2. The second source region S2 and the second drain region D2 might not overlap the gate electrode G2 in the third direction DR3. The second source region S2 and the second drain region D2 may have a desired conductivity by doping a semiconductor material with ions.

The sixth active layer ACT6 may include a sixth channel region CHA6, a sixth source region S6 and a sixth drain region D6. The sixth channel region CHA6 may overlap the gate electrode G6 in the third direction DR3 that is the thickness direction of the substrate SUB.

According to the embodiment, the length Lch6 of the sixth channel region CHA6 may be equal to or less than 3.0 micrometers. To the extent that an element is not described in detail with respect to this figure, it may be understood that the element is at least similar to a corresponding element that has been described elsewhere within the present disclosure.

The sixth source region S6 may be disposed on one side of the sixth channel region CHA6, and the sixth drain region D6 may be disposed on the opposite side of the sixth channel region CHA6. The sixth source region S6 and the sixth drain region D6 might not overlap the gate electrode G6 in the third direction DR3. The sixth source region S6 and the sixth drain region D6 may have a desired conductivity by doping a semiconductor material with ions.

According to the embodiment of the present disclosure, the sixth transistor T6 may further include the low-concentration doping region LD6. The low-concentration doping region LD6 may be adjacent to the sixth drain region D6. The low-concentration doping region LD6 may be adjacent to the sixth drain region D6 on the opposite side to the side where the sixth channel region CHA6 is disposed.

The low-concentration doping region LD6 may include a semiconductor material doped with ions, with a lower concentration than the sixth source region S6 and the sixth drain region D6.

In the process of fabricating the display device 10, the low-concentration doping region LD6 may be formed using a photoresist PR in the same process as the process of doping the sixth drain region D6 and the sixth source region S6.

According to the embodiment, the low-concentration doping region LD6 may work as a resistance pattern, and thus may control the current flow of a transistor electrically connected to the anode electrode AE. For example, the low-concentration doping region LD6 may control the current flow between the anode electrode AE and the first transistor T1 (driving transistor).

The structures of the fifth transistor T5, the seventh transistor T7 and the eighth transistor T8 may be substantially identical to the structures of the first transistor T1, the second transistor T2 and the third transistor T3. To the extent that an element is not described in detail with respect to this figure, it may be understood that the element is at least similar to a corresponding element that has been described elsewhere within the present disclosure.

The first gate insulator 133 may be disposed on the first semiconductor layer SCL1. The first gate insulator 133 may entirely cover the first semiconductor layer SCL1 and the buffer layer 131.

The first gate conductive layer CDL1 may be disposed on the first gate insulator 133. The first gate conductive layer CDL1 may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

According to the embodiment, the first gate conductive layer CDL1 may include the gate electrodes G1, G2, G5, G6, G7 and G8 included in the first transistor T1, the second transistor T2, the fifth transistor T5, the sixth transistor T6, the seventh transistor T7 and the eighth transistor T8, respectively.

According to the embodiment, the gate electrode G1 of the first transistor T1 may overlap the first channel region CHA1 of the first transistor T1, the gate electrode G2 of the second transistor T2 may overlap the second channel region CHA2 of the second transistor T2, and the sixth transistor T6 may overlap the sixth channel region CHA6 of the sixth transistor T6. To the extent that an element is not described in detail with respect to this figure, it may be understood that the element is at least similar to a corresponding element that has been described elsewhere within the present disclosure.

In addition, the first gate conductive layer CDL1 may include the third voltage line VIL, the scan write line GWL, and the bias scan line GBL. The third voltage line VIL, the scan write line GWL and the bias scan line GBL may be extended in the first direction DR1.

As described above, according to the embodiment, the gate electrode G2 of the second transistor T2 may be electrically connected to the scan write line GWL, and the gate electrode G7 of the seventh transistor T7 and the gate electrode G8 of the eighth transistor T8 may be electrically connected to the bias scan line GBL.

The second gate insulator 135 may be disposed on the first gate conductive layer CDL1. The second gate insulator 135 may entirely cover the first gate conductive layer CDL1 and the first gate insulator 133.

Referring to FIGS. 5 and 7, the display device 10, according to the embodiment, may include a valley area disposed at the periphery of a plurality of first to eighth transistors T1 to T8. In the valley area Valley, the first semiconductor layer SCL1 and the first gate conductive layer CDL1 might not overlap each other. In FIG. 7, the valley areas Valley face each other on one side and the opposite side in the second direction DR2. It should be understood, however, that the embodiments of the present disclosure are not necessarily limited thereto. The arrangement of the valley area Valley may vary depending on the embodiments.

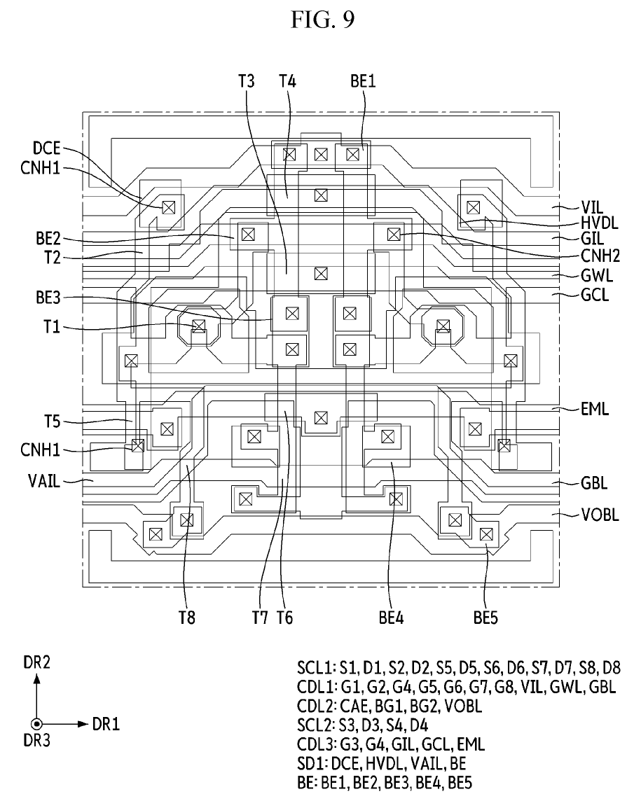

FIG. 9 is a layout diagram illustrating an example of the second gate conductive layer, the second semiconductor layer, the third gate conductive layer and the first source/drain conductive layer in FIG. 5. In the layout diagram of FIG. 9, the second gate conductive layer, the second semiconductor layer, the third gate conductive layer and the first source/drain conductive layer are additionally formed on the layout diagram of FIG. 7.

Referring to FIGS. 5 to 9, the second gate conductive layer CDL2 may be disposed on the second gate insulator 135. The second gate conductive layer CDL2 may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

According to the embodiment, the second gate conductive layer CDL2 may include the capacitor Cst, a first bottom electrode BG1, a second bottom electrode BG2, and the fifth voltage line VOBL.

The capacitor Cst may overlap the gate electrode G1 of the first transistor T1. Since the second gate insulator 135 has a dielectric constant, a capacitor may be formed between the gate electrode G1 and the capacitor Cst.

The first bottom electrode BG1 may be disposed such that it overlaps the third channel region CHA3 of the third transistor T3 and the gate electrode G3 of the third transistor T3. The first bottom electrode BG1 may be utilized as a back gate electrode for adjusting the characteristics of the third transistor T3.

The second bottom electrode BG2 may be disposed such that it overlaps the fourth channel region CHA4 of the fourth transistor T4 and the gate electrode G4 of the fourth transistor T4. The second bottom electrode BG2 may be utilized as a back gate electrode for controlling the characteristics of the fourth transistor T4.

The first interlayer dielectric layer 137 may be disposed on the second gate conductive layer CDL2. The first interlayer dielectric layer 137 may entirely cover the second gate conductive layer CDL2 and the second gate insulator 135.

The second semiconductor layer SCL2 may be disposed on the first interlayer dielectric layer 137. The second semiconductor layer SCL2 may include an oxide semiconductor. For example, the second semiconductor layer SCL2 may include IGZO (Indium (In), Gallium (Ga), Zinc (Zn) and Oxygen (O)), IGZTO (Indium (In), Gallium (Ga), Zinc (Zn), Tin (Sn) and Oxygen (O)) or IGTO (indium (In), gallium (Ga), tin (Sn) and oxygen (O)).

According to the embodiment, the second semiconductor layer SCL2 may include a third active layer ACT3 of the third transistor T3 and an active layer ACT4 of the fourth transistor T4.

The third active layer ACT3 may include a third channel region CHA3, a third source region S3 and a third drain region D3. The third channel region CHA3 may overlap the gate electrode G3 included in the third gate conductive layer CDL3 and the first bottom electrode BG1.

The third source region S3 may be disposed on one side of the third channel region CHA3, and the third drain region D3 may be disposed on the opposite side of the third channel region CHA3. The third source region S3 and the third drain region D3 might not overlap the gate electrode G3 in the third direction DR3. The third source region S3 and the third drain region D3 may have a desired conductivity by doping a semiconductor material with ions.

The fourth active layer ACT4 may include a fourth channel region CHA4, a fourth source region S4 and a fourth drain region D4. In the fourth channel region CHA4, the gate electrode G4 and the second bottom electrode BG2 included in the fourth gate conductive layer CDL4 may overlap each other.

The fourth source region S4 may be disposed on one side of the fourth channel region CHA4, and the fourth drain region D4 may be disposed on the opposite side of the fourth channel region CHA4. The fourth source region S4 and the fourth drain region D4 might not overlap the gate electrode G4 in the third direction DR3. The fourth source region S4 and the fourth drain region D4 may have a desired conductivity by doping a semiconductor material with ions.

The third gate insulator 139 may be disposed on the second semiconductor layer SCL2. The third gate insulator 139 may entirely cover the second semiconductor layer SCL2 and the first interlayer dielectric layer 137.

The third gate conductive layer CDL3 may be disposed on the third gate insulator 139. The third gate conductive layer CDL3 may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

The third gate conductive layer CDL3 according to the embodiment may include the gate electrode G3 of the third transistor T3 and the gate electrode G4 of the fourth transistor T4. The gate electrode G3 may overlap the third active layer ACT3 in the third direction DR3, and the gate electrode G4 may overlap the fourth active layer ACT4 in the third direction DR3.

In addition, according to the embodiment, the third gate conductive layer CDL3 may include the scan initialization line GIL extended in the first direction DR1, the scan control line GCL extended in the first direction DR1, and the emission control line EML extended in the first direction DR1. To the extent that an element is not described in detail with respect to this figure, it may be understood that the element is at least similar to a corresponding element that has been described elsewhere within the present disclosure.

The second interlayer dielectric layer 141 may be disposed on the third gate conductive layer CDL3. The second interlayer dielectric layer 141 may entirely cover the third gate conductive layer CDL3 and the third gate insulator 139.

The first source/drain conductive layer SD1 may be disposed on the second interlayer dielectric layer 141. The first source/drain conductive layer SD1 may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

According to the embodiment, the first source/drain conductive layer SD1 may include a data connection electrode DCE, a fourth voltage line VAIL, a second horizontal voltage line HVDL, and bridge electrodes BE.

The bridge electrodes BE may include first to fifth bridge electrodes BE1, BE2, BE3, BE4 and BE5. The first bridge electrode BE1 may connect between fourth drain regions D4 of adjacent sub-pixel. Each of the fourth drain regions D4 may be electrically connected to the first bridge electrode BE1 through a contact hole.

The second bridge electrode BE2 may connect the third drain region D3 of the third transistor T3 with the gate electrode G1 of the first transistor T1. The third drain region D3 may be electrically connected to the second bridge electrode BE2 through a second contact hole CNH2, and the gate electrode G1 may be electrically connected to the second bridge electrode BE2 through a contact hole.

The third bridge electrode BE3 may connect the third source region S3 of the third transistor T3 with the first drain region D1 of the first transistor T1. The third source region S3 may be electrically connected to the third bridge electrode BE3 through a contact hole, and the first drain region D1 may be electrically connected to the third bridge electrode BE3 through the first contact hole CNH1.

The fourth bridge electrode BE4 may assist in connecting the sixth drain region D6 of the sixth transistor T6 and the seventh source region S7 of the seventh transistor T7 to the anode electrode AE through contact holes. According to the embodiment, the fourth bridge electrode BE4 may be a first anode connection electrode ANCE1 of FIG. 6.

The first anode connection electrode ANCE1 may be electrically connected to the sixth drain region D6 of the sixth transistor T6 through the first contact hole CNH1. In addition, the first anode connection electrode ANCE1 may be electrically connected to a second anode connection electrode ANCE2 through a first anode contact hole ANCH1.

The fifth bridge electrode BE5 may connect the eighth drain region D8 of the eighth transistor T8 with the fifth voltage line VOBL. Each of the eighth drain region D8 and the fifth power line VOBL may be electrically connected to the fifth bridge electrode BE5 through a contact hole.

The data connection electrode DCE may be electrically connected to the second source region S2 of the second transistor T2 through the first contact hole CNH1. In addition, the data connection electrode DCE may be electrically connected to the data line DL through the second contact hole CNH2.

The fourth voltage line VAIL may be electrically connected to the seventh drain region D7 of the seventh transistor T7 through a contact hole. The fourth voltage line VAIL may overlap the emission control line EML and the bias scan line GBL in the third direction DR3.

The second horizontal voltage line HVDL may be electrically connected to the fifth source region S5 of the fifth transistor T5 through a contact hole. The second horizontal voltage line HVDL may overlap the scan initialization line GIL, the scan control line GCL and the scan write line GWL in the third direction DR3.

The first via layer 143 may be disposed on the first source/drain conductive layer SD1. The first via layer 143 may entirely cover the first source/drain conductive layer SD1 and the second interlayer dielectric layer 141.

The first via layer 143 may include an organic material and may provide a flat surface over the underlying structures having different heights.

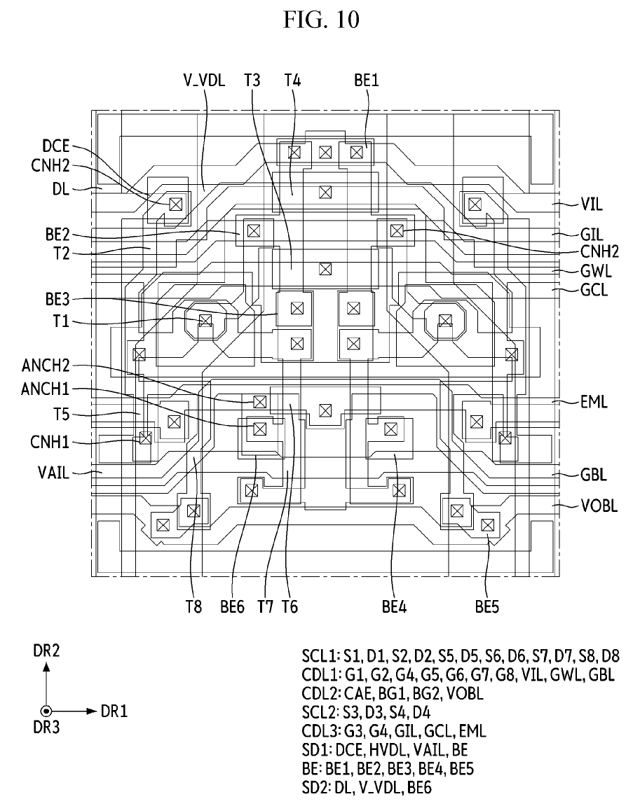

FIG. 10 is a layout diagram illustrating an example of the second source/drain conductive layer in FIG. 5. In the layout diagram of FIG. 10, the second source/drain conductive layer is additionally formed on the layout diagram of FIG. 9.

Referring to FIGS. 5 to 10, the second source/drain conductive layer SD2 may be disposed on the first via layer 143. The second source/drain conductive layer SD2 may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

According to the embodiment, the second source/drain conductive layer SD2 may include a data line DL, a second vertical voltage line V_VDL, and a sixth bridge electrode BE6.

The data line DL may be extended in the second direction DR2. The data line DL may be electrically connected to the data connection electrode DCE through the second contact hole CNH2 penetrating the first via layer 143. The data line DL may be electrically connected to the second source region S2 of the second transistor T2.

According to the embodiment, the data line DL may overlap in the third direction DR3 with the third voltage line VIL, the scan write line GWL and the bias scan line GBL included in the first gate conductive layer CDL1; the fifth voltage line VOBL included in the second gate conductive layer CDL2; the scan initialization line GIL, the scan control line GCL and the emission control line EML included in the third gate conductive layer CDL3; and the second horizontal voltage line HVDL and the fourth voltage line VAIL included in the first source/drain conductive layer SD1.

In addition, the data line DL may overlap at least one of the first to eighth transistors T1 to T8 in the third direction DR3.

The second vertical voltage line V_VDL may be extended in the second direction DR2. The second vertical voltage line V_VDL may be electrically connected to the second horizontal power line HVDL through a contact hole.

According to the embodiment, the second vertical voltage line V_VDL may overlap in the third direction DR3 with the third voltage line VIL, the scan write line GWL and the bias scan line GBL included in the first gate conductive layer CDL1; the fifth voltage line VOBL included in the second gate conductive layer CDL2; the scan initialization line GIL, the scan control line GCL and the emission control line EML included in the third gate conductive layer CDL3; and the second horizontal voltage line HVDL and the fourth voltage line VAIL included in the first source/drain conductive layer SD1.

In addition, the second vertical voltage line V_VDL may overlap at least one of the first to eighth transistors T1 to T8 in the third direction DR3.

The sixth bridge electrode BE6 may be disposed on the fourth bridge electrode BE4. The sixth bridge electrode BE6 may overlap the fourth bridge electrode BE4 in the third direction DR3. The sixth bridge electrode BE6 may be electrically connected to the fourth bridge electrode BE4 through the first anode contact hole ANCH1. The sixth bridge electrode BE6 may be the second anode connection electrode ANCE2 of FIG. 6.

The second anode connection electrode ANCE2 may overlap the first anode connection electrode ANCE1 in the third direction DR3. The second anode connection electrode ANCE2 may be electrically connected to the first anode connection electrode ANCE1 through the first anode contact hole ANCH1, and the second anode connection electrode ANCE2 may be electrically connected to a third anode connection electrode ANCE3 through a second anode contact hole ANCH2.

The second via layer 145 may be disposed on the second source/drain conductive layer SD2. The second via layer 145 may entirely cover the second source/drain conductive layer SD2 and the first via layer 143.

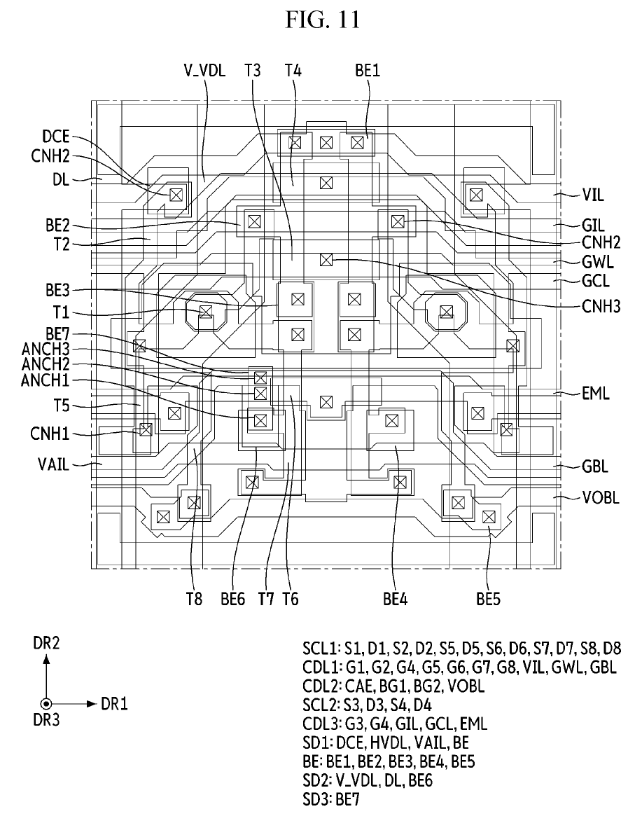

FIG. 11 is a layout diagram illustrating an example of the third source/drain conductive layer in FIG. 5. In the layout diagram of FIG. 11, the third source/drain conductive layer is additionally formed on the layout diagram of FIG. 10.

Referring to FIGS. 5 to 11, the third source/drain conductive layer SD3 may be disposed on the second via layer 145.

The third source/drain conductive layer SD3 may include a semiconductor material. For example, the third source/drain conductive layer SD3 may include oxide semiconductor, amorphous silicon, low-temperature polycrystalline silicon, etc.

According to the embodiment, the third source/drain conductive layer SD3 may include a seventh bridge electrode BE7. In a plan view, the seventh bridge electrode BE7 may be disposed on the fourth bridge electrode BE4 and the sixth bridge electrode BE6. The seventh bridge electrode BE7 may overlap the fourth bridge electrode BE4 and the sixth bridge electrode BE6 in the third direction DR3.

The seventh bridge electrode BE7 may be electrically connected to the sixth bridge electrode BE6 through the second anode contact hole ANCH2. According to the embodiment, the seventh bridge electrode BE7 may be the third anode connection electrode ANCE3 of FIG. 6.

The third anode connection electrode ANCE3 may overlap the second anode connection electrode ANCE2 and the first anode connection electrode CNE1 in the third direction DR3. The third anode connection electrode ANCE3 may be electrically connected to the second anode connection electrode ANCE2 through the second anode contact hole ANCH2, and may be electrically connected to the anode electrode AE through a third anode contact hole ANCH3.

According to the embodiment, the seventh bridge electrode BE7 or the third anode connection electrode ANCE3 may be the resistive member RM of FIG. 3. For example, the seventh bridge electrode BE7 or the third anode connection electrode ANCE3 may be electrically connected between the light-emitting element LE and the first transistor T1 (driving transistor) to work as low resistance of the driving current, thereby appropriately maintaining the driving voltage range.

For example, the electrical resistance of the seventh bridge electrode BE7 or the third anode connection electrode ANCE3 may have a value of 100 kΩ to 1,000 kΩ. The above values of the electrical resistance may be measured by a voltammeter.

The third via layer 147 may be disposed on the third source/drain conductive layer SD3. The third via layer 147 may entirely cover the third source/drain conductive layer SD3 and the second via layer 145.

The third via layer 147 may include an organic material. For example, the third via layer 147 may include an acrylic resin, a silicone resin, a silicone acrylic resin, an epoxy resin, polyimide, polyamide, benzocyclobutene, a phenol resin, etc.

As shown in FIG. 6, the display element layer DIL may be disposed on the thin-film transistor layer TFTL. The display element layer DIL may include a pixel-defining layer 151 and a light-emitting element LE.

The light-emitting element LE may be disposed on the third via layer 147. The light-emitting element LE may include an anode electrode AE, an emissive layer EL, and a common electrode CE. The light-emitting element LE refers to an element that emits light as holes from the anode electrode AE and electrons from the cathode electrode CE recombine in the emissive layer EL. Each of a plurality of light-emitting elements LE may be an organic light-emitting diode (OLED) in which the emissive layer EL is formed as an organic emissive layer, but the embodiments of the present disclosure are not necessarily limited thereto.

The anode electrode AE may be disposed on the third via layer 147. The anode electrode AE may be electrically connected to the third anode connection electrode ANCE3 through a third anode contact hole ACTH3. The anode electrode AE may be electrically connected to the sixth drain region D6 of the sixth transistor T6 through the third anode connection electrode ANCE3, the second anode connection electrode ANCE2 and the first anode connection electrode ANCE1.

According to an embodiment, the anode electrode AE may be electrically connected to the first drain region D1 of the first transistor T1 through the third anode connection electrode ANCE3, the second anode connection electrode ANCE2 and the first anode connection electrode ANCE1.

The anode electrodes AE may have a stack structure of a material layer having a high work function such as indium-tin-oxide (ITO), indium-zinc-oxide (IZO), zinc oxide (ZnO) and indium oxide (In₂O₃), and a reflective material layer such as silver (Ag), magnesium (Mg), aluminum (Al), platinum (Pt), lead (Pb), palladium (Pd), gold (Au), nickel (Ni), neodymium (Nd), iridium (Ir), chromium (Cr), lithium (Li), or a mixture thereof. For example, the anode electrodes AE may have, but is not necessarily limited to, a multilayer structure of ITO/Mg, ITO/MgF, ITO/Ag, and ITO/Ag/ITO.

The pixel-defining layer 151 may be disposed on the anode electrode AE. The pixel-defining layer 151 may cover an edge of the anode electrode AE, and may define emission openings OP. The emission areas EA and the non-emission area NLA may be defined by emission openings OP.

The pixel-defining layer 151 may assist in separating the anode electrode AE from the cathode electrode CE.

The pixel-defining layer 151 may include an organic material. For example, the pixel-defining layer 151 may include an acrylic resin, a silicone resin, a silicone acrylic resin, an epoxy resin, polyimide, polyamide, benzocyclobutene, a phenol resin, etc.

The emissive layer EL may be disposed on the anode electrode AE and the pixel-defining layer 151. The emissive layer EL may be in contact with the anode electrode AE in the emission opening OP.

Each of the emissive layers EL may include an organic material and may emit light. For example, the emissive layer EL of the first emission area EA1 may emit first light, the emissive layer EL of the second emission area EA2 may emit second light, and the emissive layer EL of the third emission area EA3 may emit third light. Each of the emissive layers EL may include a hole transporting layer, an organic material layer, and an electron transporting layer.

The cathode electrode CE may be disposed on the emissive layer EL and the pixel-defining layer 151. The cathode electrode CE may be entirely in contact with the emissive layer EL and the pixel-defining layer 151 to cover them.

In the top-emission structure, the cathode electrode CE may be formed of a transparent conductive material (TCP) such as ITO and IZO that can transmit light, or a semi-transmissive conductive material such as magnesium (Mg), silver (Ag) and an alloy of magnesium (Mg) and silver (Ag). When the cathode electrode CE is made of a translucent metal material, the emission efficiency of each of the light-emitting elements LE can be increased by using microcavities.

An encapsulation layer including at least one inorganic insulating material to prevent oxygen or moisture from permeating, and a polarizing film for preventing degradation of visibility due to external light, or a sensor electrode layer including sensor electrodes for detecting touch may be arranged on the display element layer DIL.

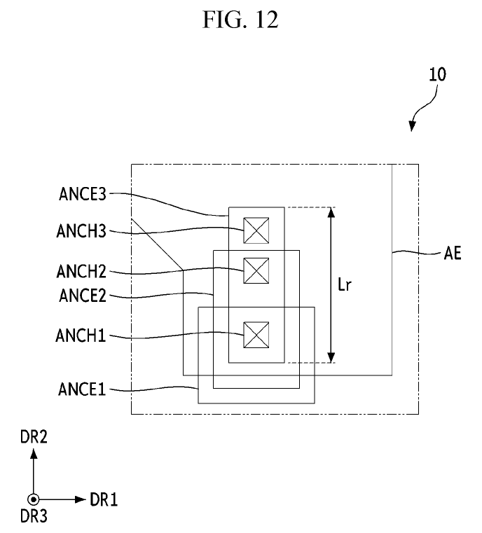

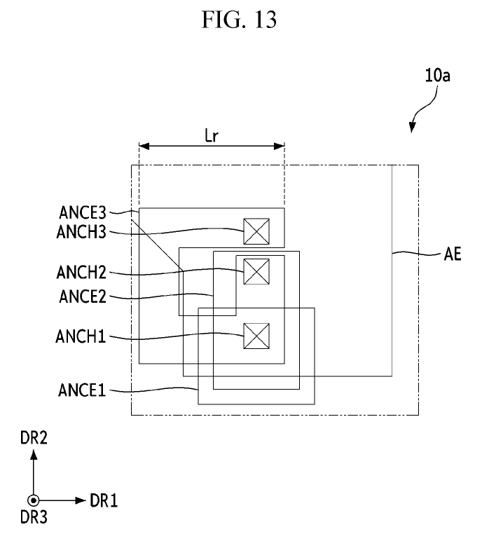

FIG. 12 is a plan view showing the layout of the first to third anode connection electrodes and the anode electrodes in FIG. 6. FIG. 13 is a plan view showing an example of the layout of the first to third anode connection electrodes and the anode electrodes in FIG. 6.

Referring to FIGS. 12 and 13, the first to third anode connection electrodes ANCE1, ANCE2 and ANCE3 may be sequentially stacked on one another in the third direction DR3 in a plan view, and the first to third anode connection electrodes ANCE1, ANCE2 and ANCE3 may overlap the anode electrode AE in the third direction DR3 in a plan view.

In a plan view, the first anode contact hole ANCH1 connecting the first anode connection electrode ANCE1 with the second anode connection electrode ANCE2 may be spaced apart from the second anode contact hole ANCH2 connecting the second anode electrode ANCE2 with a third anode electrode ANCE3. It should be understood, however, that the embodiments of the present disclosure are not necessarily limited thereto. The first anode contact hole ANCH1 and the second anode contact hole ANCH2 may be arranged at the same position in the third direction DR3.

In a plan view, the second anode contact hole ANCH2 connecting the second anode connection electrode ANCE2 with the third anode connection electrode ANCE3 may be spaced apart from the second anode contact hole ANCH2 connecting the second anode electrode ANCE2 with the third anode electrode ANCE3. It should be understood, however, that the embodiments of the present disclosure are not necessarily limited thereto. The second anode contact hole ANCH2 and the third anode contact hole ANCH may be arranged at the same position in the third direction DR3.

The display device 10, according to the embodiment, can control the resistance formed between the driving transistor and the light-emitting element by controlling the length Lr or thickness of the third anode connection electrode ANCE3.

For example, with the same thickness, the resistance may increase as the length Lr of the third anode connection electrode ANCE3 increases. For example, as shown in FIG. 13, the length Lr of a third connection electrode ANCE3 included in a display device 10a may be larger than the length Lr of the third connection electrode ANCE3 included in the display device 10. Accordingly, the third connection electrode ANCE3 included in the display device 10a may have a higher resistance than the third connection electrode ANCE3 included in the display device 10. As described above, the electrical resistance of the third connection electrode ANCE3 included in the display device 10a and the third connection electrode ANCE3 included in the display device 10 may be adjusted within the range of 100 kΩ to 1,000 kΩ.

For example, with the same length Lr, the third anode connection electrode ANCE3 may have a larger cross-sectional area as the thickness increases, and may have a higher resistance as the cross-sectional area increases.

Referring again to FIGS. 1 to 13, in the display device 10, according to the embodiment of the present disclosure, the conductive layers can be formed at a high density within a narrow area by connecting the first to third anode connection electrodes ANCE1, ANCE2 and ANCE3 by stacking them in the third direction DR3.

In addition, the display device 10, according to the embodiment of the present disclosure, includes the resistance member RM (e.g., the third anode connection electrode ANCE3) including a semiconductor material between the anode electrode AE and the first transistor T1, so that it is possible to maintain the driving voltage range appropriately even if the first channel region CHA1 of the first transistor T1 has a length of 3.0 micrometers or less. As described above, the first transistor T1, according to the embodiment of the present disclosure, may be referred to as the driving transistor.

Accordingly, the display device 10, according to the embodiment, may be employed in a high-resolution electronic device, so that the luminance (or grayscale) of the light-emitting element can be precisely adjusted even if the size of the transistor is reduced.

Thus, the display device may feature a matrix of sub-pixels each containing a driving transistor, switching transistors, a capacitor, and a self-emissive element like an OLED. Advanced circuitry, such as scan drivers, emission drivers, and a timing controller, may be used to manage data input, voltage supply, and light emission across the display area. A resistive element may be disposed between the driving transistor and the light-emitting element, which may stabilize the driving voltage and improve luminance control.

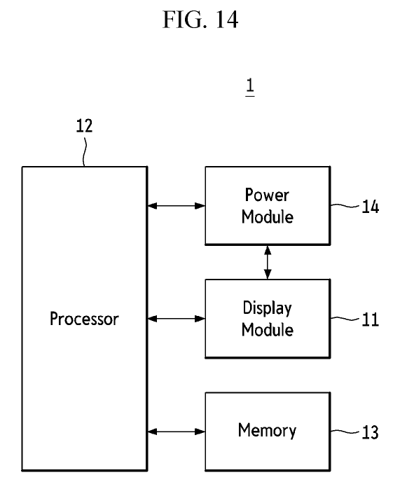

FIG. 14 is a block diagram of an electronic device according to an embodiment of the present disclosure.

Referring to FIG. 14 in conjunction with FIGS. 1 to 13, the display device 10, according to the embodiment, may be employed in a variety of electronic devices 1. The electronic device 1, according to the embodiment, may include the above-described display device 10, and may further include a module or device having additional functions in addition to the display device 10.

The electronic device 1, according to the embodiment, may include a display module 11, a processor 12, a memory 13, and a power module 14.

The processor 12 may include at least one of: a central processing unit (CPU), an application processor (AP), a graphic processing unit (GPU), a communication processor (CP), an image signal processor (ISP), and a controller.

The memory 13 may store data information required for the operation of the processor 12 or the display module 11. When the processor 12 executes an application stored in the memory 13, an image data signal and/or an input control signal may be transmitted to the display module 11. The display module 11 may process the received signal and output image information through a display screen.

The power module 14 may include a power supply module such as a power adapter and a battery device, and a power conversion module that converts the power supplied by the power supply module to generate power required for the operation of the electronic device 1.

At least one of the elements of the electronic device 1 described above may be included in the display devices according to the embodiments described above. In addition, some of the individual modules functioning as a single module may be included in the display device while some others may be provided separately from the display device. For example, the display device may include the display module 11, and the processor 12, the memory 13 and the power module 14 may be implemented as other devices inside the electronic device 1 instead of the display device.

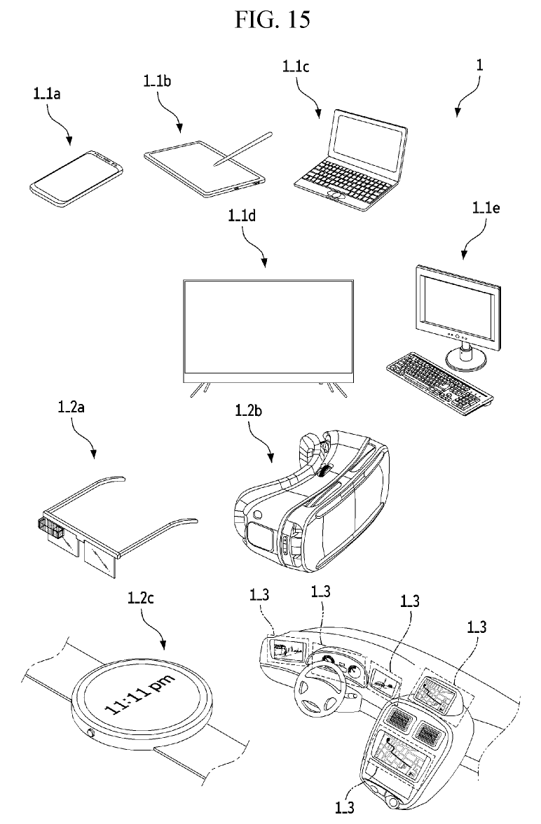

FIG. 15 is a view showing electronic devices according to a variety of embodiments of the present disclosure.

Referring to FIG. 15, a variety of electronic devices 1 employing the display devices 10 according to the embodiments may include not only image display electronic devices such as a smart phone 1_1a, a tablet computer 1_1b, a laptop/notebook computer 1_1c, a TV 1_1d and a computer monitor 1_1e, but also wearable electronic devices including display modules such as smart glasses 1_2a, a head-mounted display 1_2b and a smart watch 1_2c, and electronic devices for vehicles 1_3 including display modules such as a center information display (CID) placed on the dashboard, the center fascia and the dashboard of a vehicle, and a room mirror display.

Embodiments of the disclosure should not necessarily be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention.

What is claimed is:

1. A display device, comprising:
a substrate comprising an emission area and a non-emission area;
a thin-film transistor layer disposed on the substrate and comprising a driving transistor; and
a display element layer disposed on the thin-film transistor layer and comprising an anode electrode electrically connected to the driving transistor,
wherein the thin-film transistor layer comprises:
a first anode connection electrode disposed between the driving transistor and the anode electrode;
a second anode connection electrode disposed on the first anode connection electrode; and
a third anode connection electrode disposed on the second anode connection electrode, electrically connected to the anode electrode, and comprising a semiconductor material,
wherein the first anode connection electrode, the second anode connection electrode, the third anode connection electrode, and the anode electrode overlap one another in a direction that is perpendicular to a surface of the substrate, and
wherein the first anode connection electrode, the second anode connection electrode, the third anode connection electrode, and the anode electrode are disposed in different layers from one another.

2. The display device of claim 1, wherein the driving transistor comprises a channel region, a source region, and a drain region, and
wherein a length of the channel region of the driving transistor is equal to or less than 3.0 micrometers.

3. The display device of claim 2, further comprising:
a switching transistor disposed between the driving transistor and the first anode connection electrode,
wherein the switching transistor comprises a channel region, a source region, and a drain region,
wherein the switching transistor is electrically connected to the drain region of the driving transistor, and
wherein a length of the channel region of the switching transistor is equal to or less than 3.0 micrometers.

4. The display device of claim 3, wherein the switching transistor further comprises a low-concentration region having a lower doping concentration than the drain region of the switching transistor, and
wherein the low-concentration region of the switching transistor is electrically connected to the drain region of the switching transistor on an opposite side to a side where the channel region of the switching transistor is disposed.

5. The display device of claim 4, wherein the low-concentration region overlaps the third anode connection electrode in a direction perpendicular to the surface of the substrate.

6. The display device of claim 2, wherein the thin-film transistor layer comprises:
a first gate conductive layer disposed on the channel region of the driving transistor;
a second gate conductive layer disposed on the first gate conductive layer;
an oxide semiconductor layer disposed on the second gate conductive layer;
a third gate conductive layer disposed on the oxide semiconductor layer; and
a first source/drain conductive layer disposed on the third gate conductive layer, and
wherein the first source/drain conductive layer comprises the first anode connection electrode.

7. The display device of claim 6, wherein the thin-film transistor layer further comprises a second source/drain conductive layer disposed on the first source/drain conductive layer,
wherein the second source/drain conductive layer comprises the second anode connection electrode, and
wherein the second source/drain conductive layer further comprises a vertical voltage line and a data line.

8. The display device of claim 7, wherein the thin-film transistor layer further comprises a third source/drain conductive layer disposed on the second source/drain conductive layer, and
wherein the third source/drain conductive layer comprises the third anode connection electrode.

9. The display device of claim 8, wherein the third anode connection electrode is disposed between the data line and the anode electrode.

10. The display device of claim 1, wherein the second anode connection electrode is electrically connected to the first anode connection electrode through a first anode contact hole,
wherein the third anode connection electrode is electrically connected to the second anode connection electrode through a second anode contact hole, and
wherein the anode electrode is electrically connected to the third anode connection electrode through a third anode contact hole.

11. The display device of claim 10, wherein the second anode contact hole is spaced apart from the third anode contact hole, in a plan view.

12. The display device of claim 11, wherein the first anode connection electrode, the second anode connection electrode, the third anode connection electrode, and the anode electrode overlap one another in a direction perpendicular to the surface of the substrate, in the plan view.

13. The display device of claim 1, wherein an electrical resistance of the third anode connection electrode ranges from 100 kΩ to 1,000 kΩ.

14. The display device of claim 1, wherein the third anode connection electrode comprises at least one of an oxide semiconductor, an amorphous silicon, and a low-temperature polycrystalline silicon.

15. An electronic device, comprising:
at least one display device comprising a substrate comprising an emission area and a non-emission area; and
at least one of a display module, a processor, a memory and a power module electrically connected to the at least one display device,
wherein the at least one display device comprises:
a thin-film transistor layer disposed on the substrate and comprising a driving transistor; and
a display element layer disposed on the thin-film transistor layer and comprising an anode electrode electrically connected to the driving transistor,
wherein the thin-film transistor layer comprises:
a first anode connection electrode disposed between the driving transistor and the anode electrode;
a second anode connection electrode disposed on the first anode connection electrode; and
a third anode connection electrode disposed on the second anode connection electrode, electrically connected to the anode electrode, and comprising a semiconductor material,
wherein the first anode connection electrode, the second anode connection electrode, the third anode connection electrode, and the anode electrode overlap one another in a direction perpendicular to a surface of the substrate and are disposed in different layers from each other.

16. The electronic device of claim 15, wherein the driving transistor comprises a channel region, a source region, and a drain region, and
wherein a length of the channel region of the driving transistor is equal to or less than 3.0 micrometers.

17. The electronic device of claim 16, further comprising:
a switching transistor disposed between the driving transistor and the first anode connection electrode,
wherein the switching transistor comprises a channel region, a source region, and a drain region,
wherein the switching transistor is electrically connected to the drain region of the driving transistor, and
wherein a length of the channel region of the switching transistor is equal to or less than 3.0 micrometers.

18. The electronic device of claim 15, wherein the thin-film transistor layer comprises:
a first gate conductive layer disposed on a channel region of the driving transistor;
a second gate conductive layer disposed on the first gate conductive layer;
an oxide semiconductor layer disposed on the second gate conductive layer;
a third gate conductive layer disposed on the oxide semiconductor layer; and
a first source/drain conductive layer disposed on the third gate conductive layer, and
wherein the first source/drain conductive layer comprises the first anode connection electrode.

19. The electronic device of claim 18, wherein the thin-film transistor layer further comprises:
a second source/drain conductive layer disposed on the first source/drain conductive layer; and
a third source/drain conductive layer disposed on the second source/drain conductive layer,
wherein the second source/drain conductive layer comprises a vertical voltage line, a data line, and the second anode connection electrode, and
wherein the third source/drain conductive layer comprises the third anode connection electrode.

20. The electronic device of claim 15, wherein an electrical resistance of the third anode connection electrode ranges from 100 kΩ to 1,000 kΩ, and
wherein the third anode connection electrode comprises at least one of an oxide semiconductor, an amorphous silicon, or a low-temperature polycrystalline silicon.
